(19) United States
(12) Patent Application Publication
(10) Pub. No.: US 2016/0055055 A1
(43) Pub. Date: Feb. 25, 2016

(54) MEMORY SYSTEM AND ERROR CORRECTION DECODING METHOD

(71) Applicant: Kabushiki Kaisha Toshiba, Minato-ku (JP)

(72) Inventors: Kohsuke HARADA, Yokohama (JP); Naoaki KOKUBUN, Yokohama (JP)

(73) Assignee: Kabushiki Kaisha Toshiba, Minato-ku (JP)

(21) Appl. No.: 14/626,072

(22) Filed: Feb. 19, 2015

Related U.S. Application Data
(60) Provisional application No. 62/041,426, filed on Aug. 25, 2014.

(51) Int. Cl. G06F 11/10; H03M 13/39; G11C 29/52

(52) U.S. Cl. CPC G06F 11/1068; G11C 29/52; H03M 13/3927

(57) ABSTRACT

According to one embodiment, there is provided a memory system including a first generating unit, a buffer unit, a decoding unit, and an update unit. The first generating unit generates logarithm likelihood ratios for plural pieces of data read from a plurality of memory cells. The buffer unit stores the logarithm likelihood ratios. The decoding unit performs first error correction decoding process on the logarithm likelihood ratios, and estimates a logarithm likelihood ratio of data corresponding to an error memory cell among the plural pieces of read data. The update unit updates the logarithm likelihood ratios stored in the buffer unit using the estimated logarithm likelihood ratio.

### CROSS-REFERENCE TO RELATED APPLICATIONS

This application is based upon and claims the benefit of priority from U.S. Provisional Application No. 62/041,426, filed on Aug. 25, 2014; the entire contents of which are incorporated herein by reference.

### FIELD

Embodiments described herein relate generally to a memory system and an error correction decoding method.

### BACKGROUND

In a memory system, a controller of a memory device including a plurality of memory cells performs an error correction decoding process using an error-correcting code to correct an error of data read from a memory cell. At this time, it is desirable to appropriately implement a correction capability of an error-correcting code.

### BRIEF DESCRIPTION OF THE DRAWINGS

FIG. 1 is a diagram illustrating a configuration of a memory system according to an embodiment;

FIG. 2 is a diagram illustrating a configuration of a memory core and a read processing unit according to the embodiment;

FIG. 3 is a diagram illustrating a configuration of a non-volatile memory device according to the embodiment;

FIG. 4 is a diagram illustrating a data structure of error information according to the embodiment;

FIG. 5 is a diagram illustrating an error correction decoding process according to the embodiment;

FIG. 6 is a diagram illustrating a threshold voltage distribution of memory cells (single level cells) and reference levels according to the embodiment;

FIG. 7 is a flowchart illustrating an operation of a memory system according to the embodiment;

FIG. 8 is a diagram illustrating a configuration of a memory core and a read processing unit according to a modified example of the embodiment; and

FIG. 9 is a flowchart illustrating an operation of a memory system according to another modified example of the embodiment.

FIG. 10 is a diagram illustrating a threshold voltage distribution of a memory cells (multiple level cells) and reference levels according to the embodiment;

### DETAILED DESCRIPTION

In general, according to one embodiment, there is provided a memory system including a first generating unit, a buffer unit, a decoding unit, and an update unit. The first generating unit generates logarithm likelihood ratios for plural pieces of data read from a plurality of memory cells. The buffer unit stores the logarithm likelihood ratios. The decoding unit performs first error correction decoding process on the logarithm likelihood ratios, and estimates a logarithm likelihood ratio of data corresponding to an error memory cell among the plural pieces of read data. The update unit updates the logarithm likelihood ratios stored in the buffer unit using the estimated logarithm likelihood ratio.

Exemplary embodiments of a memory system will be explained below in detail with reference to the accompanying drawings. The present invention is not limited to the following embodiments.

### Embodiments

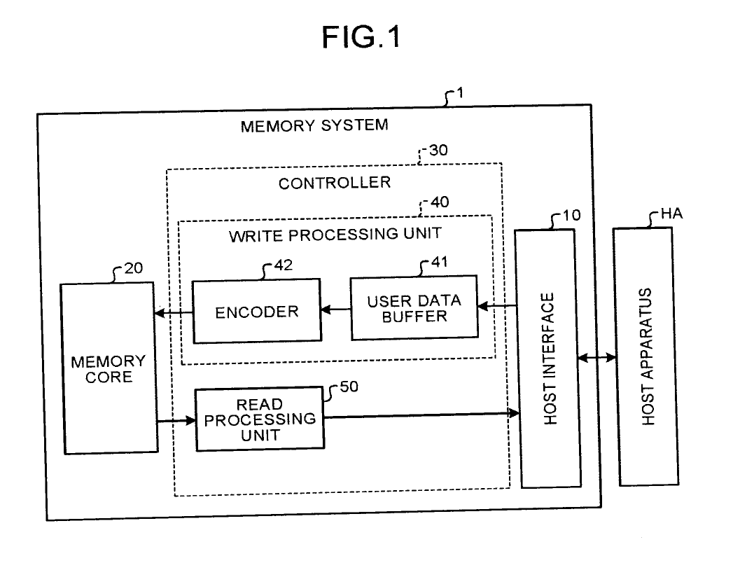

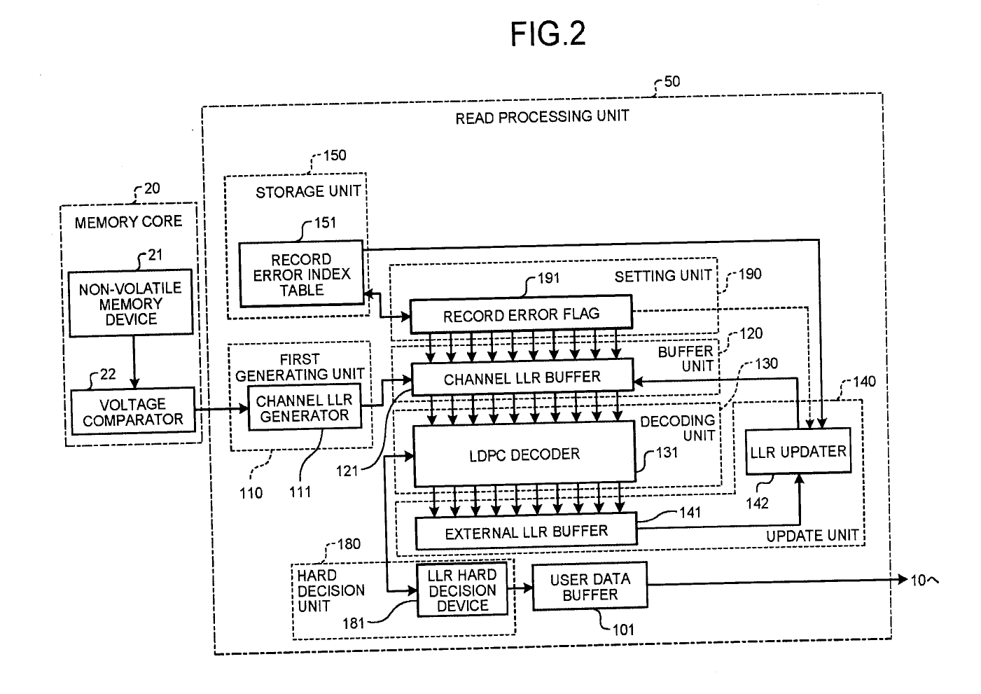

A memory system 1 according to an embodiment will be described with reference to FIGS. 1 and 2. FIG. 1 is a diagram illustrating a configuration of the memory system 1. FIG. 2 is a diagram illustrating a configuration of a memory core 20 and a read processing unit 50.

The memory system 1 is connected to a host apparatus HA via a communication medium, and functions as an external storage medium for the host apparatus HA. For example, the host apparatus HA includes a personal computer (PC) or a central processing unit (CPU) core. For example, the memory system 1 includes a solid state drive (SSD).

The memory system 1 stores data in the memory core 20 according to a write command received from the host apparatus HA, and reads data stored in the memory core 20 according to a read command received from the host apparatus HA. There are cases in which it is difficult to read data stored in the memory core 20. For this reason, at the time of data writing, an error-correcting code is added to data and stored in the memory core 20 as coded data. Then, at the time of data reading, an error correction decoding process is performed. In the error correction decoding process, coded data is decoded to generate an error-correcting code, and error correction is performed using the generated error-correcting code. In the present embodiment, a low density parity check (LDDC) code can be used as an error-correcting code.

Specifically, the memory system 1 includes a host interface 10, the memory core 20, and a controller 30.

Upon receiving a write command and write data from the host apparatus HA, the host interface 10 provides the write command and the write data to the controller 30. Upon receiving a write completion notification from the controller 30, the host interface 10 transmits the write completion notification to the host apparatus HA.

Further, upon receiving a read command from the host apparatus HA, the host interface 10 provides the read command to the controller 30. Upon receiving read data from the controller 30, the host interface 10 transmits the read data to the host apparatus HA.

The memory core 20 includes a non-volatile memory device 21 (see FIG. 2). In the non-volatile memory device 21, a plurality of memory cells MC are arranged. The plurality of memory cells MC may be three-dimensionally arranged. Hereinafter, to simplify the explanation, a case where each memory cell MC is a single level cell (SLC) that can store one bit is exemplified.

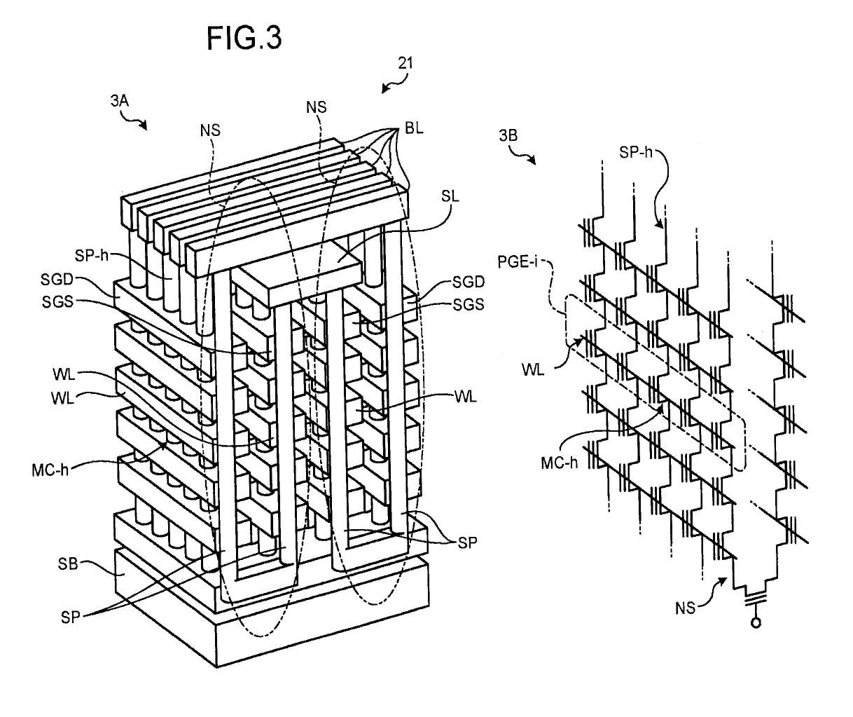

For example, as illustrated in FIG. 3A, the non-volatile memory device 21 includes a semiconductor substrate SB, three or more conductive layers, and a string SP. The three or more conductive layers are stacked on the semiconductor substrate SB to be insulated from one another. The string SP includes a plurality of semiconductor poles. The plurality of semiconductor poles penetrate the three or more conductive layers, lower ends of the semiconductor poles are positioned on the semiconductor substrate SB side, and the lower ends are connected to one another to form a letter “U” shape in a cross-sectional view. The plurality of semiconductor poles equivalently function as NAND strings NS as illustrated in FIG. 3B. The plurality of memory cells MC are formed in each string SP. Further, the non-volatile memory device 21 includes a plurality of bit lines BL, a select gate line SGD at the plurality of bit lines BL side, a word line WL, and a select gate line SGS at the plurality of source lines SL side. The plurality of bit lines BL are arranged above the three or more conductive layers to be insulated from the three or more conductive layers, and extend in a first direction. Further, the select gate line SGD at the plurality of bit lines BL side is configured with a topmost conductive layer among the three or more conductive layers, and extend in a second direction orthogonal to the first direction. The word lines WL serving as a control gate line are configured with the conductive layers excluding the topmost layer among the three or more conductive layers. The plurality of memory cells MC connected to the same word line WL can configure a page PGE serving as a unit (a management unit of the controller 30) of a read operation and a write operation by the controller 30.

In the non-volatile memory device 21, as the memory cells MC are decreased in size, a manufacturing accuracy variation of the memory cell MC increases, and thus a record error memory cell in which charges are hardly recorded may occur. In the non-volatile memory device 21 having the record error memory cell, it is possible to specify the record error memory cell by pre-training. For example, when a string SP-h illustrated in FIG. 3A is found to be electrically disconnected through inspection at the time of manufacturing the non-volatile memory device 21, a memory cell MC corresponding to the string SP-h can be specified as an error memory cell. For example, for data of a page PGE-i illustrated in FIG. 3B, a memory cell MC-h having an address “h” corresponding to the string SP-h can be specified to be an error memory cell.

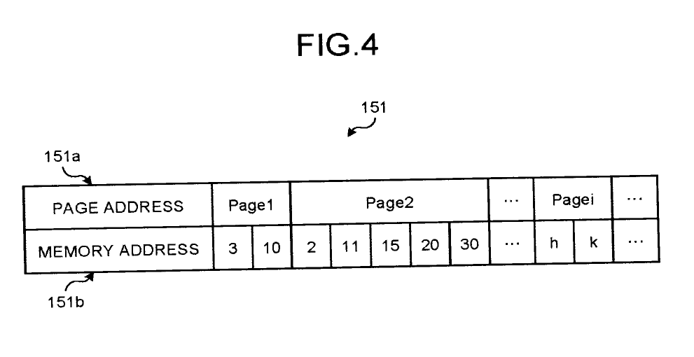

It is possible to specify an error memory cell for each page PGE in advance. Thus, for example, a record error index table 151 illustrated in FIG. 4 can be configured with results of specifying error memory cells as error information. The record error index table 151 includes identifiers of error memory cells for a plurality of pages PGE. In the record error index table 151, a memory address and a page address of an error memory cell are associated with each other for a plurality of error memory cells. The record error index table 151 includes a page address column 151a and a memory address column 151b. A page address is recorded in the page address column 151a as information identifying a page. A memory address is recorded in the memory address column 151b as information identifying a memory cell MC. It is possible to specify a memory cell MC serving as an error memory cell for each page with reference to the record error index table 151. For example, it is understood that a page PGE of a page address “Page i” includes an error memory cell of a memory address “h” and an error memory cell of a memory address “k.”

The controller 30 illustrated in FIG. 1 includes a write processing unit 40 and the read processing unit 50. The write processing unit 40 includes a user data buffer 41 and an encoder 42. When write data is received from the host interface 10, the user data buffer 41 temporarily holds the write data. The encoder 42 receives the write data from the user data buffer 41, and performs an error-correction coding process on the write data. In other words, the encoder 42 generates an error-correcting code (for example, an LDPC code) on the write data, adds an error-correcting code to the write data, and generates coded data. The encoder 42 writes the generated coded data in a plurality of memory cells MC of a page PGE unit in the memory core 20.

The read processing unit 50 reads data from the memory cell MC selected in the memory core 20. At this time, the read processing unit 50 performs the error correction decoding process using an error-correcting code (for example, an LDPC code) for correcting an error of the read data of the memory cell MC. The read processing unit 50 provides the read data that has been subjected to the error correction decoding process to the host interface 10.

However, when there is an error memory cell among a plurality of memory cells MC of a read target, data read from the error memory cell is likely to have a read error. Due to this influence, there is a possibility that performing the error correction decoding process using the error-correcting code (for example, the LDPC code) can become difficult, and that the error-correcting code is unlikely to show its original correction capability.

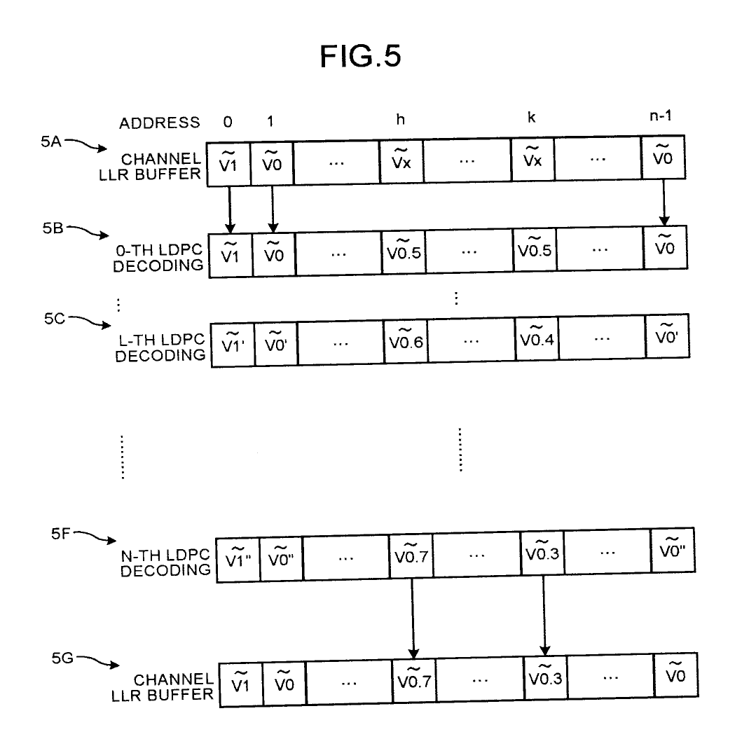

For example, in the error correction decoding process for data encoded using an LDPC code, the read processing unit 50 calculates an initial value of a logarithm likelihood ratio (LLR) indicating the likelihood of data initially as illustrated in FIG. 5A. In other words, the read processing unit 50 generates information for indicating a probability of “0” (hereinafter, the likelihood of “0”) of a bit value and a probability of “1” (hereinafter, the likelihood of “1”) for each read data of the memory cell MC using an LDPC code. Then, the read processing unit 50 calculates a logarithm likelihood ratio (LLR) (=log(“likelihood that bit value of data will be “0””/“likelihood that bit value of data will be “1””). According to this definition, when the LLR is negative, the likelihood that the bit value of data will be “1” is high, whereas when the LLR is positive, the likelihood that the bit value of data will be “0” is high.

In the case of FIG. 5A, the read processing unit 50 calculates “V1^{˜}” indicating that the likelihood that the bit value will be “1” is high, as a logarithm likelihood ratio (LLR) of data of a memory cell MC of an address “0.” The read processing unit 50 calculates “V0^{˜}” indicating that the likelihood that the bit value will be “0” is high, as a logarithm likelihood ratio (LLR) of data of a memory cell MC of an address “1.” The read processing unit 50 calculates “V0^{˜}” indicating that the likelihood that the bit value will be “0” is high, as a logarithm likelihood ratio (LLR) of data of a memory cell MC of an address “n−1.” At this time, when data read from the memory cells MC of the addresses “h” and “k” has a read error, the read processing unit 50 calculates “Vx^{˜}” indicating that a bit value has an indefinite level, as logarithm likelihood ratios (LLR) of data of the memory cells MC of the addresses “h” and “k.” In other words, the read processing unit 50 is likely to erroneously recognize that an LLR value is very large (reliability is high), although actual reliability of data read from a record error memory cell is very low.

Then, in the error correction decoding process, the read processing unit 50 repeatedly performs error correction decoding according to an iteration technique, based on the initial value of the logarithm likelihood ratio. At this time, the read processing unit 50 performs the error correction decoding by applying an LDPC code to plural pieces of neighboring logarithm likelihood ratios. For this reason, for example, when the error correction decoding is performed on plural pieces of logarithm likelihood ratios illustrated in FIG. 5A, the logarithm likelihood ratios of data of the normal memory cells gradually decrease in reliability and degrades due to influence of the logarithm likelihood ratio (for example, the logarithm likelihood ratios “Vx^{˜}” of the addresses “h” and “k”) of the record error memory cell.

For example, as the error correction decoding is performed L times as illustrated in FIG. 5B and FIG. 5C, the logarithm likelihood ratio of the address “0” degrades from “V1^{˜}” indicating that the likelihood that the bit value will be “1” is high to “V1^{˜}” closer to 0. The logarithm likelihood ratio of the address “1” degrades from “V0^{˜}” indicating that the likelihood that the bit value will be “0” is high to “V0′^{˜}” closer to 0. Then, as the error correction decoding is further performed (N−L) times (N is an integer larger than L) as illustrated in FIG. 5C and FIG. 5F, the logarithm likelihood ratio of the address “0” degrades from the degraded “V1′^{˜}” to “V1″^{˜}” further closer to 0. The logarithm likelihood ratio of the address “1” degrades from the degraded “V0′^{˜}” to “V0″^{˜}” further closer to 0.

In other words, the whole decoding performance tends to degrade due to influence of a cell indicating a very high LLR value although the actual reliability is very low. Since it is difficult to distinguish between read error from a record error memory cell and read error from a normal memory cell, it is difficult to prevent degradation in a correction capability of error correction decoding even when an LDPC code is applied.

Further, when an alternate memory cell to an already known record error memory cell is secured in the non-volatile memory device 21 in order to prevent a read error of data, the efficient use of a plurality of memory cells MC is hindered. For example, when an alternate memory cell to an error memory cell for data of a first page is secured in a second page, it is necessary to perform the read operation twice, that is, the read operation for the first page and the read operation for the second page to acquire data of all memory cells of the first page. Further, due to the alternate memory cell, the number of bits of data that can be stored in the second page decreases. In order to efficiently use a plurality of memory cells MC in the non-volatile memory device 21, it is desirable to appropriately implement a correction capability of an error-correcting code and restore data of an error memory cell without securing an alternate memory cell to an error memory cell.

In this regard, in the present embodiment, logarithm likelihood ratios of plural pieces of data including logarithm likelihood ratios of normal memory cells are acquired, preliminary error correction decoding (first error correction decoding process) is performed, and a logarithm likelihood ratio of an error memory cell is estimated. By repeating′ this operation, it is possible to gradually improve the accuracy of the logarithm likelihood ratio of the error memory cell. Then, among the logarithm likelihood ratios of plural pieces of data, the logarithm likelihood ratio of the error memory cell is selectively updated using the estimated logarithm likelihood ratio, that is, the logarithm likelihood ratio whose accuracy has been improved. Thus, the original error correction decoding (second error correction decoding process) is performed using the logarithm likelihood ratios of the normal memory cells and the logarithm likelihood ratio of the error memory cell whose accuracy has been improved, and thus the correction capability of the error-correcting code (LDPC cede) can be appropriately implemented.

Specifically, the read processing unit 50 stores an index (for example, ‘a page address’+‘a memory address’) of a record error memory cell) in the record error index table 151 (see FIG. 4) in advance. Then, the read processing unit 50 sets a bit corresponding to a record error memory cell in a record error flag 191 with reference to the record error index table 151. Then, the read processing unit 50 sets an LLR value corresponding to a bit set by the record error flag 191 to LLR=0. In other words, the read processing unit 50 sets an initial setting value (a predetermined initial setting value) indicating a state in which a probability of 0 is equal to a probability of 1, and reliability is lowest as a logarithm likelihood ratio (LLR) of read data of a record error memory cell.

For example, the read processing unit 50 stores a logarithm likelihood ratio of a page PGE unit obtained by the soft decision in a buffer unit 120 (a channel LLR buffer 121) as illustrated in FIG. 5A. Then, the read processing unit 50 sets a predetermined initial setting value “V0.5^{˜}” as a decoding target instead of setting the logarithm likelihood ratio “Vx^{˜}” obtained as a decoding target as the logarithm likelihood ratios of the error memory cells of the addresses “h” and “k” by the soft decision as illustrated in FIG. 5B. The initial setting value “V0.5^{˜}” indicates the logarithm likelihood ratio (LLR=0) in which a probability of 0 and a probability of 1 are equal. Further, the read processing unit 50 sets the logarithm likelihood ratios of the normal memory cells (logarithm likelihood ratios other than those of the addresses “h” and “k”) among the logarithm likelihood ratios of the pages PGE stored in the channel LLR buffer 121 as the decoding target.

The read processing unit 50 applies a sum-product algorithm or a min-sum algorithm that is one of LDPC decoding algorithms to the record error memory cell in a state in which the LLR value is set to 0. Then, the preliminary error correction decoding is repeatedly performed. As a result, it is possible to calculate an external LLR value (an LLR estimation value) obtained by a restraint condition of an LDPC code for bit information of the record error memory cell in which the LLR value is set to 0. The external LLR value does not include LLR value information read from the memory cell MC at all.

For example, as illustrated in FIG. 5C, the read processing unit 50 performs the preliminary error correction decoding L (L is an integer of 1 or more) times. Thus, the logarithm likelihood ratio of the error memory cell of the address “h” is estimated to be “V0.6^{˜}” that is higher in reliability than the initial setting value “V0.5^{˜}.” The logarithm likelihood ratio of the error memory cell of the address “k” is estimated to be “V0.4^{˜}” that is higher in reliability than the initial setting value “V0.5^{˜}.” “V0.6” indicates a logarithm likelihood ratio (LLR) when “likelihood that bit value of data will be “0””/“likelihood that bit value of data will be “1”” is 0.6 as an example. “V0.4^{˜}” indicates a logarithm likelihood ratio (LLR) when “likelihood that bit value of data will be “0””/“likelihood that bit value of data will be “1”” is 0.4 as an example. In other words, the logarithm likelihood ratio of the error memory cell is influenced by the logarithm likelihood ratios of the normal memory cells and thus can be improved in reliability.

Then, as illustrated in FIG. 5F, the read processing unit 50 further performs the preliminary error correction decoding (N−L) times (N is an integer larger than L). As a result, the logarithm likelihood ratio of the error memory cell of the address “h” is estimated to be “V0.7^{˜}” that is higher in reliability than the L-th value “V0.6^{˜}.” The logarithm likelihood ratio of the error memory cell of the address “k” is estimated to be “V0.3^{˜}” that is higher in reliability than the L-th value “V0.4^{˜}.” “V0.7^{˜}” indicates a logarithm likelihood ratio (LLR) when “likelihood that bit value of data will be “0””/“likelihood that bit value of data will be “1”” is 0.7 as an example. “V0.3^{˜}” indicates a logarithm likelihood ratio (LLR) when “likelihood that bit value of data will be “0””/“likelihood that bit value of data will be “1”” is 0.3 as an example.

Then, the read processing unit 50 overwrites the LLR value corresponding to the bit set by the record error flag 191 as the record error memory cell by the external LLR value (the LLR estimation value) obtained by the above decoding algorithm. As a result, the LLR value of the bit in which the LLR value of the bit information for the record error memory cell was initially 0 is overwritten to a non-zero LLR value (LLR≠0).

For example, as illustrated in FIG. 5G, the read processing unit 50 accesses the buffer unit 120 (the channel LLR buffer 121), and overwrites and updates the logarithm likelihood ratio of the error memory cell among the logarithm likelihood ratios obtained as a result of performing N-th preliminary error correction decoding. In other words, the read processing unit 50 overwrites and updates the logarithm likelihood ratio for the memory cell of the address “h” among plural pieces of logarithm likelihood ratios stored in the buffer unit 120 (the channel LLR buffer 121) to “V0.7^{˜}.” The logarithm likelihood ratio for the memory cell of the address “k” is overwritten and updated to “V0.3^{˜}.”

Plural pieces of logarithm likelihood ratios stored in the buffer unit 120 include the logarithm likelihood ratio “V0.7^{˜}” estimated for the address “h” and the logarithm likelihood ratio “V0.3^{˜}” estimated for the address “k.” Among plural pieces of logarithm likelihood ratios stored in the buffer unit 120, the logarithm likelihood ratios for the other addresses have the same values as the initial values set in FIG. 5B. In other words, in plural pieces of logarithm likelihood ratios, while using the logarithm likelihood ratios that are higher in reliability as the logarithm likelihood ratio of the error memory cell, the initial values are used instead of the degraded values as the logarithm likelihood ratios of the normal memory cells.

With the decoding operation by the above procedure, decoding can be performed in view of the presence of the record error memory cell, for data of a page that is hardly decoded when LDPC decoding is performed in a state in which the presence of the record error memory cell is not known. In other words, the logarithm likelihood ratio of the error memory cell can be gradually improved to a value having higher reliability by influence of the logarithm likelihood ratios of the normal memory cells. Then, the original error correction decoding is performed using the logarithm likelihood ratio of the error memory cell improved to a value having higher reliability and the logarithm likelihood ratios of the normal memory cell that are the initial values having higher reliability. Accordingly, a success probability of LDPC decoding can be maintained to be high.

Next, detailed configurations of the memory core 20 and the read processing unit 50 will be described with reference to FIG. 2.

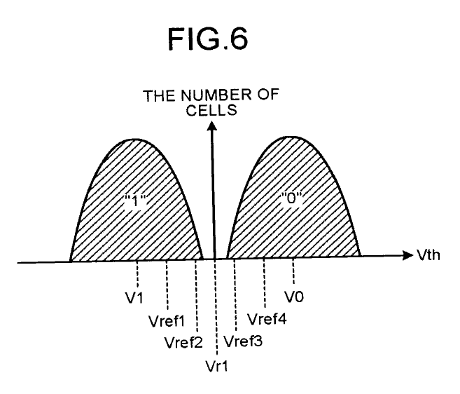

The memory core 20 includes a voltage comparator 22 in addition to the non-volatile memory device 21. The voltage comparator 22 compares a read voltage (threshold voltage) of the memory cell MC with a reference level, and generates a comparison result indicating whether the threshold voltage of the memory cell MC is close to a level V0 of the bit value “0” or is close to a level V1 of the bit value “1.” For example, the voltage comparator 22 has a first reference level Vref1, a second reference level Vref2, a boundary reference level Vr1, a third reference level Vref3, and a fourth reference level Vref4, as shown in FIG. 6. FIG. 6 is a diagram illustrating a threshold voltage distribution of memory cells (single level cells) and reference levels. For example, a magnitude relation among the reference levels is V1<Vref1<Vref2<Vr1<Vref3<Vref4<V0. The voltage comparator 22 provides the comparison result to the read processing unit 50. The boundary reference level Vr1 is a level that forms the boundary between a threshold voltage region of the bit value “0” and a threshold voltage region of the bit value “1.”

It should be noted that coded data read from the non-volatile memory device 21 in units of pages PGE includes a data part and a redundancy part. The redundancy part includes an error-correcting code (LDPC code).

The read processing unit 50 includes a first generating unit 110, the buffer unit 120, a storage unit 150, a setting unit 190, a decoding unit 130, an update unit 140, a hard decision unit 180, and a user data buffer 101.

The first generating unit 110 receives the determination result from the voltage comparator 22. The first generating unit 110 includes a channel LLR generator 111. The channel LLR generator 111 generates the logarithm likelihood ratios (LLRs) on each of plural pieces of data read from a plurality of memory cells MC of a page PGE unit according to the determination result of the data part and the determination result of the error-correcting code (LDPC code).

For example, when the threshold voltage of the memory cell MC is equal to or less than the first reference level Vref1, the first generating unit 110 generates the logarithm likelihood ratios (LLRs) indicating that the threshold voltage of the memory cell MC is close to the level V1 of the bit value “1.” When the threshold voltage of the memory cell MC is larger than the first reference level Vref1 and equal to or less than the second reference level Vref2, the first generating unit 110 generates the logarithm likelihood ratios (LLRs) indicating that the threshold voltage of the memory cell MC is slightly close to the level V1 of the bit value “1.” When the threshold voltage of the memory cell MC is larger than the second reference level Vref2 and less than the boundary reference level Vr1, the first generating unit 110 generates the logarithm likelihood ratios (LLRs) indicating that the threshold voltage of the memory cell MC is slightly close to the level V1 of the bit value “1.” When the threshold voltage of the memory cell MC is larger than the boundary reference level Vr1 and equal to or less than the third reference level Vref3, the first generating unit 110 generates the logarithm likelihood ratios (LLRs) indicating that the threshold voltage of the memory cell MC is slightly close to the level V0 of the bit value “0.” When the threshold voltage of the memory cell MC is larger than the third reference level Vref3 and equal to or less than the fourth reference level Vref4, the first generating unit 110 generates the logarithm likelihood ratios (LLRs) indicating that the threshold voltage of the memory cell MC is slightly close to the level V0 of the bit value “0.” When the threshold voltage of the memory cell MC is larger than the fourth reference level Vref4, the first generating unit 110 generates the logarithm likelihood ratios (LLRs) indicating that the threshold voltage of the memory cell MC is close to the level V0 of the bit value “0.”

In other words, the first generating unit 110 generates a logarithm likelihood ratio (LLR) for each of plural pieces of data read from a plurality of memory cells of a page PGE unit. The first generating unit 110 provides the logarithm likelihood ratios (LLRs) of the plural pieces of data to the buffer unit 120.

The buffer unit 120 stores the logarithm likelihood ratios of the plural pieces of data. The buffer unit 120 includes the channel LLR buffer 121. The channel LLR buffer 121 is a page buffer, and configured to be able to store bit values of as many bits as the page PGE. The channel LLR buffer 121 stores the logarithm likelihood ratios of the plural pieces of data provided from the first generating unit 110 (see FIG. 5A).

The storage unit 150 stores error information related to an error memory cell. For example, the storage unit 150 stores the record error index table 151 as the error information. For example, the error information includes the record error index table 151 illustrated in FIG. 4. The record error index table 151 is acquired by specifying error memory cells in each page by an experiment (for example, an inspection at the time of manufacturing) in advance, and includes identifiers of error memory cells for a plurality of pages PGE. In the record error index table 151, a memory address and a page address of an error memory cell are associated for a plurality of error memory cells. It is possible to specify a memory cell MC serving as an error memory cell for each page with reference to the record error index table 151. For example, it is understood that a page PGE of a page address “Page1” includes an error memory cell of a memory address “3” and an error memory cell of a memory address “10.”

The setting unit 190 illustrated in FIG. 2 specifies data corresponding to an error memory cell among plural pieces of read data based on the error information. For example, the setting unit 190 includes the record error flag 191. The record error flag 191 includes as many bits as a bit number corresponding to the channel LLR buffer 121, and all bits are set to an inactive state (for example, “0”) in an initial state.

When data is read from the non-volatile memory device 21 in units of pages PGE, the setting unit 190 recognizes an identifier of a page PGE of a read target, accesses the storage unit 150, and refers to the record error index table 151. Then, the setting unit 190 specifies an identifier (a memory address) of an error memory cell in the page PGE of the read target. For example, when the identifier of the page PGE of the read target is “Page i,” the setting unit 190 specifies the address “h” and the address “k” as the identifier of the error memory cell. The setting unit 190 sets bits corresponding to the error memory cells in the record error flag 191 to an active state (for example, “1”). For example, when the identifier of the page POE of the read target is “Page i,” the setting unit 190 sets bits corresponding to the address “h” and the address “k” to the active state.

Then, the setting unit 190 sets the logarithm likelihood ratio of the data specified as the error memory cell among the logarithm likelihood ratios of the plural pieces of data stored in the buffer unit 120 to a predetermined initial setting value according to the record error flag 191. In other words, the setting unit 190 sets an LLR value of a bit corresponding to a bit set by the record error flag 191 among a plurality of bits of the channel LLR buffer 121 to LLR=0. For example, when the identifier of the page PGE of the read target is “Page i,” the setting unit 190 sets the predetermined initial setting value “V0.5^{˜}” to the logarithm likelihood ratio of the decoding target as the logarithm likelihood ratios of the error memory cells of the addresses “h” and “k” as illustrated in FIG. 5B. The initial setting value “V0.5^{˜}” indicates the logarithm likelihood ratio (LLR=0) in which a probability of 0 is equal to a probability of 1.

The decoding unit 130 illustrated in FIG. 2 accesses the buffer unit 120, and acquires logarithm likelihood ratios of plural pieces of data. The decoding unit 130 performs the preliminary error correction decoding on the logarithm likelihood ratios of the plural pieces of data. For example, the decoding unit 130 includes an LDPC decoder 131. The LDPC decoder 131 applies the sum-product algorithm or the min-sum algorithm to the logarithm likelihood ratios of the plural pieces of data, and performs the preliminary error correction decoding. Through this operation, the decoding unit 130 estimates a logarithm likelihood ratio of data corresponding to an error memory cell.

For example, as illustrated in FIG. 5B and FIG. 5C, the LDPC decoder 131 sets the predetermined initial setting value “V0.5^{˜}” as the decoding target as the logarithm likelihood ratios of the error memory cells of the addresses “h” and “k” instead of setting the logarithm likelihood ratio “Vx^{˜}” generated by the first generating unit 110 as the decoding target. The LDPC decoder 131 sets the logarithm likelihood ratio (initial value) obtained by the soft decision as the decoding target as the logarithm likelihood ratios of the normal memory cells. The LDPC decoder 131 performs the preliminary error correction decoding N times. As a result, the logarithm likelihood ratio of the error memory cell of the address “h” is estimated to be “V0.6^{˜}” that is higher in reliability than the initial setting value “V0.5^{˜}.” The logarithm likelihood ratio of the error memory cell of the address “k” is estimated to be “V0.4^{˜}” that is higher in reliability than the initial setting value “V0.5^{˜}.”

The decoding unit 130 provides the decoding result including the estimated logarithm likelihood ratio of the error memory cell to the update unit 140. Further, for example, when the original error correction decoding is performed M times, the decoding unit 130 provides the decoding result to the hard decision unit 180.

The update unit 140 updates the logarithm likelihood ratios stored in the buffer unit 120 using the estimated logarithm likelihood ratios. The update unit 140 includes an external LLR buffer 141 and an LLR updater 142. The external LLR buffer 141 can be a page buffer, and configured to be able to store bit values of as many bits as the page PGE. The external LLR buffer 141 stores the decoding result (for example, see FIG. 5C and FIG. 5F) provided from the decoding unit 130.

When the decoding result is stored in the external LLR buffer 141, the LLR updater 142 recognizes the identifier of the page PGE of the read target, accesses the storage unit 150, and refers to the record error index table 151. Then, the LLR updater 142 specifies the identifier (the memory address) of the error memory cell in the page PGE of the read target. For example, when the identifier of the page PGE of the read target is “Page i,” the setting unit. 190 specifies the address “h” and the address “k” as the identifier of the error memory cell. The LLR updater 142 accesses the external LLR buffer 141, and acquires the logarithm likelihood ratio stored in the bit corresponding to the identifier of the error memory cell, that is, the logarithm likelihood ratio of the error memory cell. The LLR updater 142 accesses the channel LLR buffer 121, and overwrites and updates the logarithm likelihood ratio stored in the bit corresponding to the error memory cell using the acquired logarithm likelihood ratio. In other words, the update unit 140 selectively updates the logarithm likelihood ratio of data corresponding to the error memory cell among the logarithm likelihood ratios of the plural pieces of data stored in the buffer unit 120.

The hard decision unit 180 determines whether or not the decoding unit 130 has successfully performed the error correction decoding according to the provided decoding result. The hard decision unit 180 includes an LLR hard decision device 181. The LLR hard decision device 181 performs the hard decision according to the decoding result, calculates a syndrome, and determines whether or not the decoding unit 130 has successfully performed the error correction decoding. When the decoding unit 130 is determined to have successfully performed the error correction decoding (syndrome=0), the LLR hard decision device 181 causes the hard decision result (bits decided to be 0/1) to be stored in the user data buffer 101. When the decoding unit 130 is determined to have failed in the error correction decoding (syndrome≠0), the LLR hard decision device 181 returns the determination result to the decoding unit 130. Thus, the decoding unit 130 performs the error correction decoding again in response to the determination result indicating that the error correction decoding has failed.

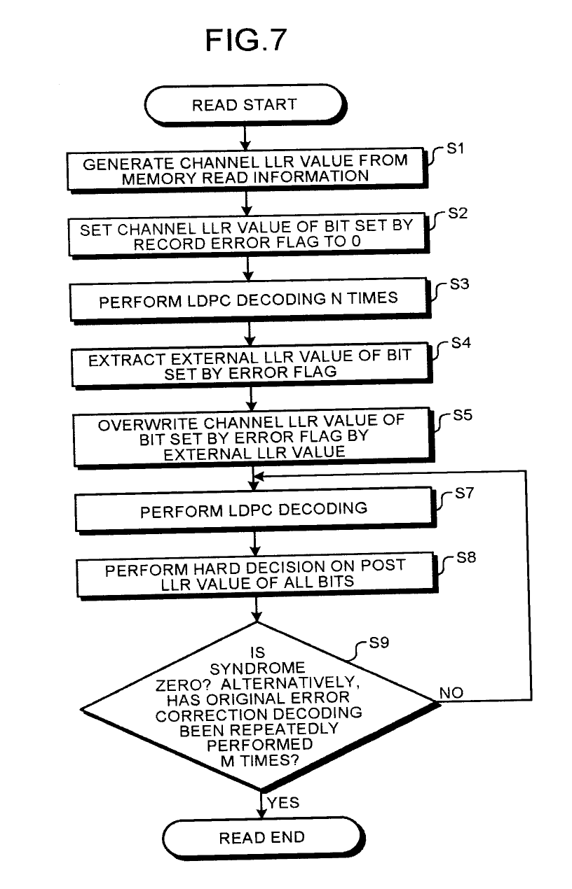

Next, an operation of the memory system 1 will be described with reference to FIG. 7. FIG. 7 is a flowchart illustrating an operation of the memory system 1.

In the memory system 1, the controller 30 generates the logarithm likelihood ratio (the LLR value) for each of data of the memory cells MC read from the non-volatile memory device 21, and stores the logarithm likelihood ratio (the LLR value) in the buffer unit 120 (S1). The controller 30 sets the LLR value corresponding to the bit set by the record error flag 191 among the logarithm likelihood ratios of the plural pieces of data stored in the buffer unit 120 to LLR=0 (S2). The controller 30 performs the preliminary error correction decoding (LDPC decoding) N times (S3). The controller 30 extracts the logarithm likelihood ratio (the external LLR value) corresponding to the bit set by the record error flag 191 from the decoding result of S3 (S4). The controller 30 overwrites and updates the LLR value corresponding to the bit set by the record error flag 191 among the logarithm likelihood ratios of the plural pieces of data stored in the buffer unit 120 by the logarithm likelihood ratio (the external LLR value) extracted in S4 (S5).

The controller 30 performs the error correction decoding (LDPC decoding) (S7). Then, the controller 30 performs the hard decision for the logarithm likelihood ratio (post LLR value) obtained by the decoding of S7 on all bits of the read target data, and calculates a syndrome (38).

The controller 30 determines whether or not at least one of a first condition and a second condition has been satisfied according to the syndrome calculation result (S9). The first condition refers to a condition indicating that the decoding unit 130 has successfully performed the error correction decoding. The second condition refers to a condition indicating that the original error correction decoding (S7) has been repeatedly performed M times (M is an integer larger than N). When the syndrome is not 0 and the number of repetitions of S7 is smaller than M (No in S9), the controller 30 determines that the decoding unit 130 has failed in the error correction decoding but there is a room for improvement, and causes the process to return to S7. When the syndrome is not 0 and the number of repetitions of S7 is larger than M (Yes in S9), the controller 30 determines that the decoding unit 130 has failed in the error correction decoding and no improvement is expected, and ends the process. When the syndrome is 0 regardless of the number of repetitions of S7 (Yes in S9), the controller 30 determines that the decoding unit 130 has successfully performed the error correction decoding, and ends the process.

As described above, in the embodiment, in the memory system 1, the decoding unit 130 acquires the logarithm likelihood ratios of plural pieces of data stored in the buffer unit 120, performs the preliminary error correction decoding, and estimates a logarithm likelihood ratio of data of an error memory cell. The update unit 140 updates the logarithm likelihood ratios stored in the buffer unit 120 using the logarithm likelihood ratio estimated by the decoding unit 130. Thus, among the logarithm likelihood ratios of the plural pieces of data stored in the buffer unit 120, it is possible to improve the accuracy of the logarithm likelihood ratio of the error memory cell, and it is possible to maintain the logarithm likelihood ratios of the normal memory cells to be an initial value before the accuracy degrades. As a result, it is possible to perform the original error correction decoding using the logarithm likelihood ratios of the normal memory cells and the logarithm likelihood ratio of the error memory cell whose accuracy has been improved, and thus it is possible to prevent degradation in decoding performance of data of a management unit (page unit).

Accordingly, since it is unnecessary to secure an alternate memory cell to an error memory cell, a plurality of memory cells MC can be efficiently used in the non-volatile memory device 21. Further, since degradation in decoding performance of data of a management unit can be prevented without securing an alternate memory cell to an error memory cell, the use efficiency of a plurality of memory cells MC in the non-volatile memory device 21 can be maintained to be high, and the correction capability of the error-correcting code (LDPC code) can be appropriately implemented.

Further, in the embodiment, in the memory system 1, the storage unit 150 stores the error information related to the error memory cell. The update unit 140 selectively updates the logarithm likelihood ratio of data of the error memory cell among the logarithm likelihood ratios of the plural pieces of data stored in the buffer unit 120 based on the error information. Thus, among the logarithm likelihood ratios of the plural pieces of data stored in the buffer unit 120, the accuracy of the logarithm likelihood ratio of the error memory cell can be selectively improved.

Further, in the embodiment, in the memory system 1, the setting unit 190 sets the logarithm likelihood ratio of data corresponding to the error memory cell among the logarithm likelihood ratios of the plural pieces of data stored in the buffer unit 120 to a predetermined initial setting value based on the error information. For example, the setting unit 190 first allocates LLR=0 to the LLR value for the record error cell, and deals it as if it were lost. The decoding unit 130 performs the preliminary error correction decoding on the logarithm likelihood ratios of the plural pieces of data including the logarithm likelihood ratio set to the initial setting value. Thus, the accuracy of the logarithm likelihood ratio of the error memory cell can be improved based on an LLR value that is more neutral than when an indefinite LLR value “Vx^{˜}” obtained by the soft decision is used for the error memory cell. As a result, the accuracy of the logarithm likelihood ratio of the error memory cell can be easily improved.

Further, in the embodiment, in the memory system 1, the error information (the record error index table 151) includes the identifiers of the error memory cells for a plurality of page units (the management units of the controller 30). Thus, the accuracy of the logarithm likelihood ratio of the error memory cell can be easily improved for each page.

Further, in the embodiment, in the memory system 1, the decoding unit 130 repeatedly estimates the logarithm likelihood ratio of the error memory cell. Thus, the accuracy of the logarithm likelihood ratio of the error memory cell can be steadily improved.

Further, in the embodiment, in the memory system 1, the decoding unit 130 estimates the logarithm likelihood ratio through the decoding unit 130 a certain number of times, updates the logarithm likelihood ratios through the update unit 140, and thereafter performs the original error correction decoding on the logarithm likelihood ratios of the plural pieces of data stored in the buffer unit 120. Thus, the original error correction decoding can be performed in a state in which the accuracy of the logarithm likelihood ratio of the error memory cell has been improved to be larger than a required level, and the correction capability of the error-correcting code (LDPC code) can be appropriately implemented.

It should be noted, as indicated by a dotted arrow in FIG. 2, the LLR updater 142 of the update unit 140 may specify the error memory cell in the page PGE of the read target with reference to the record error flag 191. In this case, since the LLR updater 142 need not recognize the identifier of the page PGE of the read target, processing of the LLR updater 142 can be simplified.

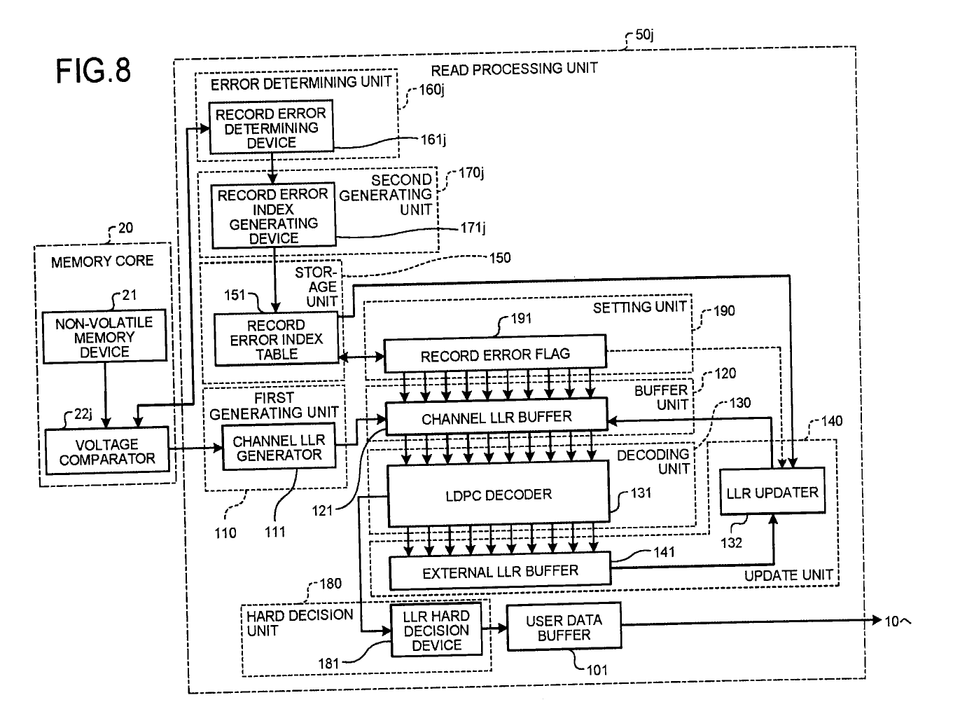

Alternatively, the record error memory cell may be specified through another memory data read method. In other words, the error information (the record error index table 151) may be generated by the read processing unit 50 instead of being acquired by an experiment in advance. For example, a read processing unit 50j may further include an error determining unit 160j and a second generating unit 170j as illustrated in FIG. 8.

For example, a voltage comparator 22j further has a fifth reference level Vref5 and a sixth reference level Vref6. The fifth reference level Vref5 and the sixth reference level Vref6 are reference levels used to determine an error. For example, a magnitude relation among the reference levels is Vref5<V1<Vref1<Vref2<Vr1<Vref3<Vref4<V0<Vref6. The voltage comparator 22j provides a comparison result to the read processing unit 50j.

The error determining unit 160j receives the comparison result from the voltage comparator 22j. The error determining unit 160j determines whether or not each of a plurality of memory cells MC of a read target is an error memory cell based on the comparison result. The error determining unit 160j includes a record error determining device 161. For example, when the threshold voltage of the memory cell MC is equal to or less than the fifth reference level Vref5, the record error determining device 161j determines the memory cell MC to be the error memory cell. When the threshold voltage of the memory cell MC is larger than the sixth reference level Vref6, the record error determining device 161j determines the memory cell MC to be the error memory cell. The error determining unit 160j provides the determination result to the second generating unit 170j.

The second generating unit 170j generates the error information based on the determination result of the error determining unit 160j. The second generating unit 170j includes a record error index generating device 171j. For example, when data is read from the non-volatile memory device 21 in units of pages PGE, the record error index generating device 171j recognizes the identifier of the page PGE of the read target. Further, the record error index generating device 171j specifies the identifier of the error memory cell in the page PGE based on the determination result of the error determining unit 160j. Based on the specifying result, the record error index generating device 171j generates the record error index table 151, and stores the record error index table 151 in the storage unit 150.

It should be noted that, in the operation of the memory system 1 illustrated in FIG. 7, the process of generating the record error index table 151 may be performed in S1. In other words, the process of generating the record error index table 151 may be performed in parallel with the process of generating the logarithm likelihood ratios of data of a plurality of memory cells MC of the read target.

In this way, since the error memory cell can be specified when data is read from the non-volatile memory device 21, the accuracy of the logarithm likelihood ratio of the error memory cell can be improved even for an error memory cell that occurs later due to degradation over time.

Alternatively, instead of using the record error index table initially, after the normal error correction decoding is performed, and the failure of the error correction decoding process is decided, the record error index table may be acquired, and the preliminary error correction decoding process may be performed. In other words, the setting unit 190 illustrated in FIG. 2 is on standby without setting the initial setting value until the failure of the error correction decoding process is decided. The buffer unit 120 stores the logarithm likelihood ratio (initial value) generated by the first generating unit 110 in each bit. Instead of estimating the logarithm likelihood ratio of data corresponding to the error memory cell, for example, the decoding unit 130 performs the error correction decoding on the logarithm likelihood ratios of the plural pieces of data stored in the buffer unit 120 M times, and provides the decoding result to the hard decision unit 180. The hard decision unit 180 determines whether or not the decoding unit 130 has successfully performed the error correction decoding. When the decoding unit 130 is determined to have failed in the error correction decoding, the hard decision unit 180 returns the determination result to the decoding unit 130. When the decoding unit 130 is determined to have filed in the error correction decoding, the decoding unit 130 requests the setting unit 190 to set the initial setting value. The setting unit 190 sets the logarithm likelihood ratio of data corresponding to the error memory cell among the logarithm likelihood ratios of the plural pieces of data stored in the buffer unit 120 to the predetermined initial setting value (LLR=0) in response to the request. When the initial setting value setting completion is confirmed, the decoding unit 130 acquires the logarithm likelihood ratios of the plural pieces of data stored in the buffer unit 120, and performs the preliminary error correction decoding. Thus, the decoding unit 130 estimates the logarithm likelihood ratio of data corresponding to the error memory cell among plural pieces of data of the read target. The update unit 140 updates the logarithm likelihood ratios stored in the buffer unit 120 using the logarithm likelihood ratio estimated by the decoding unit 130.

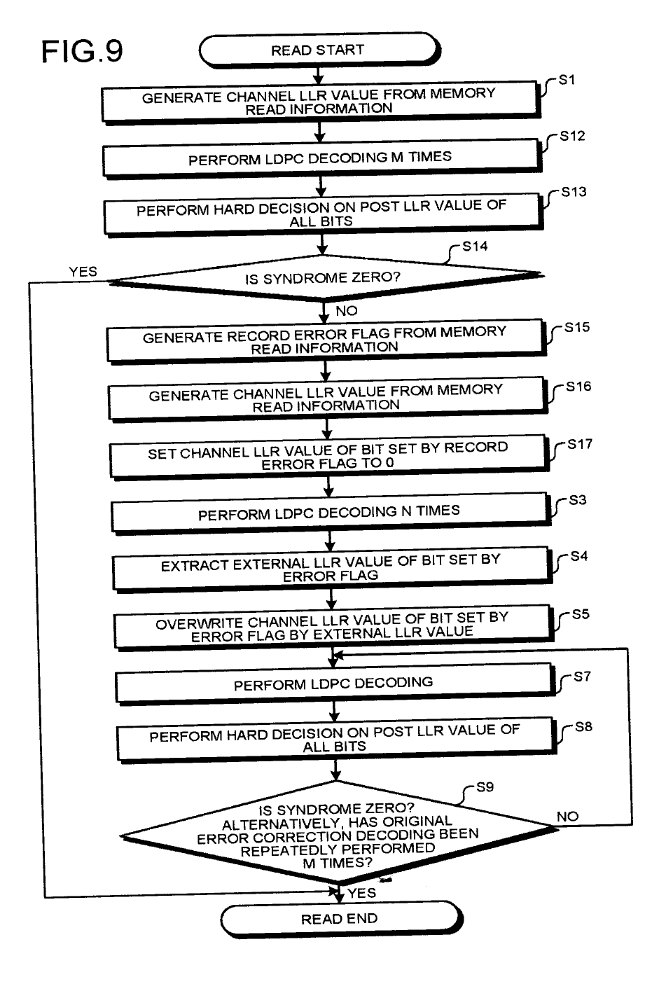

Further, in the operation of the memory system 1, the processes of S12 to S17 can be performed instead of S2 (see FIG. 7) as illustrated in FIG. 9. In other words, the controller 30 performs the error correction decoding (LDPC decoding) (S12). Then, the controller 30 performs the hard decision for the logarithm likelihood ratio (post LLR value) obtained by the decoding of S7 on all bits of the read target data, and calculates a syndrome (S13).

The controller 30 determines whether or not the decoding unit 130 has successfully performed the error correction decoding based on the syndrome calculation result (S14). When the syndrome is not 0 (No in S14), the controller 30 determines that the decoding unit 130 has failed in the error correction decoding, and causes the process to proceed to S15. When the syndrome is 0 (Yes in S14), the controller 30 determines that the decoding unit 130 has successfully performed the error correction decoding, and ends the process.

The controller 30 determines whether or not the memory cell MC is the error memory cell based on a comparison result of comparing the threshold voltage of the memory cell MC with the fifth reference level Vref5 and the sixth reference level Vref6. The controller 30 generates the record error index table 151 based on the determination result. The controller 30 sets the bit corresponding to the error memory cell among a plurality of bits of the record error flag 191 to the active state based on the record error index table 151. Through this operation, the controller 30 generates the record error flag 191 (S15).

The controller 30 generates the logarithm likelihood ratio (the LLR value) for each of data of the memory cells MC read from the non-volatile memory device 21, and stores the logarithm likelihood ratio (the LLR value) in the buffer unit 120 (S16).

The controller 30 sets the LLR value corresponding to the bit set by the record error flag 191 among the logarithm likelihood ratios of the plural pieces of data stored in the buffer unit 120 to the initial setting value (LLR=0) (S17).

Since the preliminary error correction decoding (S3) is performed after the failure of the original error correction decoding is decided as above, the occurrence frequency of the preliminary error correction decoding can be reduced. Accordingly, a total time required for the read process in the read processing unit 50 can be reduced.

Alternatively, although the case where each memory cell MC is a single level cell (SLC) that can store one bit is exemplified, each memory cell MC can be a multiple level cell (MLC) that can store plural bits.

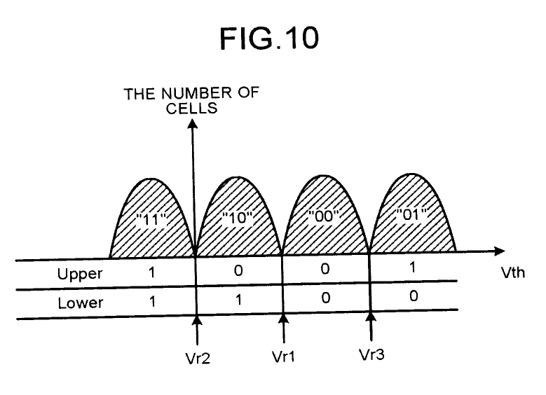

For example, each memory cell MC can store two bits as shown in FIG. 10. FIG. 10 is a diagram illustrating a threshold voltage distribution of memory cells (multiple level cells) and reference levels. Each memory cell can store any one of 4-value data “xy” defined by upper page data “x” and lower page data “y”.

For the 4-value data “xy”, for example, data items “11”, “01”, “00”, and “10” are allocated in the order of the threshold voltage of the memory cell MC. The data “11” indicates, for example, an erase state in which the threshold voltage of the memory cell MC is negative. However, the data allocation rule is not limited thereto. For example, data of three bits or more may be stored in one memory cell MC.

The read processing unit 50 generates logarithm likelihood ratios (LLRs) for the lower page data using the boundary reference level Vr1 and reference levels above or below the boundary reference level Vr1. The read processing unit 50 performs preliminary error correction decoding (first error correction decoding process) and the original error correction decoding (second error correction decoding process) in this order. With this operation, the read processing unit 50 restores the lower page data.

Then, the read processing unit 50 performs similar operation to the lower page data for the upper page data, according to the restored lower page data.

For example, in a case where the lower page data is “1”, the read processing unit 50 generates logarithm likelihood ratios (LLRs) for the upper page data using the boundary reference level Vr2 and reference levels above or below the boundary reference level Vr2. The read processing unit 50 performs preliminary error correction decoding (first error correction decoding process) and the original error correction decoding (second error correction decoding process) in this order. With this operation, the read processing unit 50 restores the upper page data.

For example, in a case where the lower page data is “0”, the read processing unit 50 generates logarithm likelihood ratios (LLRs) for the upper page data using the boundary reference level Vr3 and reference levels above or below the boundary reference level Vr3. The read processing unit 50 performs preliminary error correction decoding (first error correction decoding process) and the original error correction decoding (second error correction decoding process) in this order. With this operation, the read processing unit 50 restores the upper page data.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a first generating unit that generates logarithm likelihood ratios for plural pieces of data read from a plurality of memory cells;
a buffer unit that stores the logarithm likelihood ratios;
a decoding unit that performs first error correction decoding process on the logarithm likelihood ratios, and estimates a logarithm likelihood ratio of data corresponding to an error memory cell among the plural pieces of read data; and
an update unit that updates the logarithm likelihood ratios stored in the buffer unit using the estimated logarithm likelihood ratio.

2. The memory system according to claim 1, further comprising,
a storage unit that stores error information related to the error memory cell,
wherein the update unit selectively updates the logarithm likelihood ratio of the data corresponding to the error memory cell among the logarithm likelihood ratios of the plural pieces of data stored in the buffer unit based on the error information.

3. The memory system according to claim 2, further comprising,
a setting unit that sets the logarithm likelihood ratio of the data corresponding to the error memory cell among the stored logarithm likelihood ratios of the plural pieces of data to an initial setting value based on the error information,
wherein the decoding unit performs the first error correction decoding process on the logarithm likelihood ratios of the plural pieces of data including the logarithm likelihood ratio set to the initial setting value.

4. The memory system according to claim 2,
wherein the buffer unit stores the logarithm likelihood ratios of the plural pieces of data read from a plurality of memory cells of a management unit, and
the error information includes an identifier of the error memory cell for a plurality of management units.

5. The memory system according to claim 2, further comprising:
an error determining unit that determines whether or not each of the plurality of memory cells is an error memory cell; and
a second generating unit that generates the error information based on a determination result of the error determining unit.

6. The memory system according to claim 1,
wherein the decoding unit performs the first error correction decoding process on the logarithm likelihood ratios of the plural pieces of data including the updated logarithm likelihood ratio twice or more, and estimates the logarithm likelihood ratio of the data corresponding to the error memory cell among the plural pieces of read data.

7. The memory system according to claim 6,
wherein the decoding unit performs second error correction decoding process on the stored logarithm likelihood ratios of the plural pieces of data, after execution of the first error correction decoding process and estimation of the logarithm likelihood ratio by the decoding unit and update of the logarithm likelihood ratio by the update unit are performed, the first error correction decoding process being a preliminary error correction decoding process with respect to the second error correction decoding process.

8. The memory system according to claim 6, further comprising,
a setting unit that sets the logarithm likelihood ratio of the data corresponding to the error memory cell among the stored logarithm likelihood ratios of the plural pieces of data to an initial setting value,
wherein the decoding unit performs the first error correction decoding process on the logarithm likelihood ratios of the plural pieces of data including the logarithm likelihood ratio set to the initial setting value twice or more, and estimates the logarithm likelihood ratio of the data corresponding to the error memory cell.

9. The memory system according to claim 1,
wherein the decoding unit performs second error correction decoding process on the stored logarithm likelihood ratios of the plural pieces of data, after execution of the first error correction decoding process and estimation of the logarithm likelihood ratio by the decoding unit and update of the logarithm likelihood ratio by the update unit are performed, the first error correction decoding process being a preliminary error correction decoding process with respect to the second error correction decoding process.

10. The memory system according to claim 1,
wherein the decoding unit performs second error correction decoding process on the stored logarithm likelihood ratios of the plural pieces of data without estimating the logarithm likelihood ratio of the data corresponding to the error memory cell,
the memory system further comprises a hard decision unit that determines whether or not the decoding unit has successfully performed the second error correction decoding process,
in a case where the decoding unit has failed in the second error correction decoding process, the decoding unit performs the first error correction decoding process on the logarithm likelihood ratios, and estimates the logarithm likelihood ratio of the data corresponding to the error memory cell among the plural pieces of read data, the first error correction decoding process being a preliminary error correction decoding process with respect to the second error correction decoding process, and
in a case where the decoding unit has failed in the second error correction decoding process, the update unit updates the logarithm likelihood ratios stored in the buffer unit using the estimated logarithm likelihood ratio.

11. An error correction decoding method, comprising:
generating logarithm likelihood ratios for plural pieces of data read from a plurality of memory cells;
storing the logarithm likelihood ratios in a buffer unit;
performing first error correction decoding process on the logarithm likelihood ratios and estimating a logarithm likelihood ratio of data corresponding to an error memory cell among the plural pieces of read data; and
updating the logarithm likelihood ratios stored in the buffer unit using the estimated logarithm likelihood ratio.

12. The error correction decoding method according to claim 11,
wherein the updating includes selectively updating the logarithm likelihood ratio of the data corresponding to the error memory cell among the logarithm likelihood ratios of the plural pieces of data stored in the buffer unit based on error information related to the error memory cell.

13. The error correction decoding method according to claim 12, further comprising,
setting the logarithm likelihood ratio of the data corresponding to the error memory cell among the stored logarithm likelihood ratios of the plural pieces of data to an initial setting value based on the error information,
wherein the estimating includes performing the first error correction decoding process on the logarithm likelihood ratios of the plural pieces of data including the logarithm likelihood ratio set to the initial setting value.

14. The error correction decoding method according to claim 12,
wherein the storing includes storing the logarithm likelihood ratios of the plural pieces of data read from a plurality of memory cells of a management unit in the buffer unit, and
the error information includes an identifier of the error memory cell for a plurality of management units.

15. The error correction decoding method according to claim 12, further comprising:
determining whether or not each of the plurality of memory cells is an error memory cell; and
generating the error information based on a result of the determining.

16. The error correction decoding method according to claim 11, further comprising,
performing the first error correction decoding process on the logarithm likelihood ratios of the plural pieces of data including the updated logarithm likelihood ratio twice or more and estimating the logarithm likelihood ratio of the data corresponding to the error memory cell among the plural pieces of read data.

17. The error correction decoding method according to claim 16, further comprising,
performing second error correction decoding process on the stored logarithm likelihood ratios of the plural pieces of data, after the estimation of the logarithm likelihood ratio and the update of the logarithm likelihood ratio by execution of the first error correction decoding process are performed, the first error correction decoding process being a preliminary error correction decoding process with respect to the second error correction decoding process.

18. The error correction decoding method according to claim 16, further comprising,
setting the logarithm likelihood ratio of the data corresponding to the error memory cell among the stored logarithm likelihood ratios of the plural pieces of data to an initial setting value,
wherein the estimating includes performing the first error correction decoding process on the logarithm likelihood ratios of the plural pieces of data including the logarithm likelihood ratio set to the initial setting value twice or more and estimating the logarithm likelihood ratio of the data corresponding to the error memory cell.

19. The error correction decoding method according to claim 11, further comprising,
performing second error correction decoding process on the stored logarithm likelihood ratios of the plural pieces of data, after the estimation of the logarithm likelihood ratio and the update of the logarithm likelihood ratio by execution of the first error correction decoding process are performed, the first error correction decoding process being a preliminary error correction decoding process with respect to the second error correction decoding process.

20. The error correction decoding method according to claim 11, further comprising:
performing second error correction decoding process on the stored logarithm likelihood ratios of the plural pieces of data without estimating the logarithm likelihood ratio of the data corresponding to the error memory cell, the first error correction decoding process being a preliminary error correction decoding process with respect to the second error correction decoding process; and
determining whether or not second error correction decoding process in which estimation of a logarithm likelihood ratio is not performed has been successfully performed,
wherein the estimating the logarithm likelihood ratio is performed in a case where the second error correction decoding process in which estimation of a logarithm likelihood ratio is not performed has failed, and
the updating the logarithm likelihood ratio is performed in a case where the second error correction decoding process in which estimation of a logarithm likelihood ratio is not performed has failed.
